(19) United States
(12) Patent Application Publication
(10) Pub. No.: US 2025/0254950 A1
(43) Pub. Date: Aug. 7, 2025

(54) THIN FILM TRANSISTOR, METHOD FOR FABRICATING THE SAME, AND DISPLAY PANEL

(71) Applicant: Yungu (Gu’an) Technology Co., Ltd., Langfang (CN)

(72) Inventors: Fa-Hsyang CHEN, Langfang (CN); Xue LIU, Langfang (CN); Dejian WANG, Langfang (CN); Yinghai MA, Langfang (CN); Rubo XING, Langfang (CN); Junfeng LI, Langfang (CN)

(73) Assignee: Yungu (Gu’an) Technology Co., Ltd., Langfang (CN)

(21) Appl. No.: 19/189,157

(22) Filed: Apr. 24, 2025

Related U.S. Application Data
(63) Continuation of application No. PCT/CN2023/087676, filed on Apr. 11, 2023.

(30) Foreign Application Priority Data
Nov. 29, 2022 (CN) 202211506816.2

(51) Int. Cl. H10D 62/60; H01L 21/02; H01L 21/265; H10D 30/01; H10D 30/67; H10D 86/01; H10D 86/40; H10D 86/60

(52) U.S. Cl. CPC H10D 62/60; H01L 21/02238; H01L 21/02271; H01L 21/2652; H10D 30/0314; H10D 30/6704; H10D 30/6731; H10D 86/0229; H10D 86/421; H10D 86/60

(57) ABSTRACT

Embodiments of the present application provide a thin film transistor, a method for fabricating the thin film transistor, and a display panel. The thin film transistor includes: a substrate; an active layer formed on the substrate; a gate insulation layer located on a side of the active layer facing away from the substrate; and a gate electrode located on a side of the gate insulation layer facing away from the active layer, where in a direction from the gate insulation layer to the substrate, the concentration of implanted ions in at least a partial region of the active layer has a decreasing trend, and the concentration of implanted ions in the gate insulation layer is less than the concentration of implanted ions in the active layer. The present application can relieve the problem of display image sticking caused by driving hysteresis of thin film transistors.

### CROSS-REFERENCE TO RELATED APPLICATIONS

This application is a continuation application of International Application No. PCT/CN 2023/087676, filed on Apr. 11, 2023, which claims priority to Chinese Patent Application No. 202211506816.2, entitled “THIN FILM TRANSISTOR, DISPLAY PANEL, AND FABRICATING METHOD FOR THIN FILM TRANSISTOR” and filed on Nov. 29, 2022, all of which are hereby incorporated by reference in their entireties.

### FIELD

The present application relates to the field of display equipment, and in particular to a thin film transistor, a method for fabricating the thin film transistor, a display panel.

### BACKGROUND

An organic light-emitting diode (OLED) is an active light-emitting device. Compared with a conventional liquid crystal display (LCD) method, an OLED display technology does not require a backlight and has a self-luminescence characteristic. The OLED uses a thin film layer of an organic material and a glass substrate. When a current passes through the film layer of the organic material, the organic material emits light. Therefore, an OLED display panel can significantly save power, can be made lighter and thinner, withstands a wider range of temperature changes than an LCD display panel, and has a larger viewing angle. The OLED display panel is expected to become the next generation of flat panel display technology after LCD, and is currently one of the flat panel display technologies that have attracted most attention.

The OLED display panel mainly has a thin film transistor for display drive, the thin film transistor includes an active layer, a source/drain electrode and a gate electrode, and an implantation process increases the number of defects in the active layer, causing the deterioration of image sticking.

### SUMMARY

Embodiments of the present application provide a thin film transistor, method for fabricating the thin film transistor, and a display panel, with a view to solving the problem that the display effect of a display panel is affected by the unstable characteristics of the thin film transistor.

An embodiment of a first aspect of the present application provides a thin film transistor, including: a substrate; an active layer formed on the substrate; a gate insulation layer located on a side of the active layer facing away from the substrate; and a gate electrode located on a side of the gate insulation layer facing away from the active layer, where in a direction from the gate insulation layer to the substrate, a concentration of implanted ions in at least a partial region of the active layer has a decreasing trend, and the concentration of implanted ions in the gate insulation layer is less than the concentration of implanted ions in the active layer.

According to an implementation of the first aspect of the present application, the concentration of implanted ions in the gate insulation layer is zero.

An embodiment of a second aspect of the present application further provides a display panel, including a thin film transistor according to any one of the above-described embodiments in the first aspect.

An embodiment of a third aspect of the present application further provides a method for fabricating a thin film transistor. The fabricating method includes:
providing an active material layer on a substrate, and patterning the active material layer to form an active layer;
further providing a sacrificial layer on the substrate, the sacrificial layer covering the active layer;
implanting ions in the active layer; and
removing the sacrificial layer, and further fabricating the gate insulation layer on the substrate to form the thin film transistor.

According to an implementation of the third aspect of the present application, in the step of further providing a sacrificial layer on the substrate, the sacrificial layer covering the active layer:
the active layer is cleaned with 03 to form the sacrificial layer containing oxide, and the sacrificial layer has a thickness in the range of 1 nm-5 nm.

In the thin film transistor according to the embodiments of the present application, the thin film transistor includes the substrate, and the active layer, the gate insulation layer and the gate electrode that are arranged on the substrate. There are implanted ions in the active layer, and a concentration of implanted ions in the active layer has a decreasing trend in a direction from the gate insulation layer to the substrate, that is, ion implantation energies for the active layer vary at different thickness positions. The concentration of implanted ions in the gate insulation layer is less than the concentration of implanted ions of the active layer, such that the impact of a high concentration of implanted ions in the gate insulation layer on the characteristics of the thin film transistor can be reduced. In a direction close to the gate insulation layer, the doping concentration of the implanted ions in the active layer increases, allowing current carriers to better flow in an interface of the active layer facing the gate electrode, thereby relieving the problem of driving hysteresis of the thin film transistor. When the thin film transistor is used in a display panel, the problem of display image sticking caused by the driving hysteresis of the thin film transistor can be relieved.

### BRIEF DESCRIPTION OF THE DRAWINGS

FIG. 1 is a structural schematic diagram of a thin film transistor according to an embodiment of the present application;

FIG. 2 is a graph of the concentration of implanted ions in a thin film transistor according to an embodiment of a first aspect of the present application;

FIG. 3 is a graph of the concentration of implanted ions in a thin film transistor according to another embodiment of the first aspect of the present application;

FIG. 4 is a graph of the concentration of implanted ions in a method for fabricating a thin film transistor provided in the related art;

FIG. 5 is a schematic flow chart of a method for fabricating a thin film transistor according to an embodiment of a third aspect of the present application;

FIGS. 6 to 10 are diagrams of a process of a method for fabricating a thin film transistor according to an embodiment of the third aspect of the present application; and

FIG. 11 is a graph of the concentration of implanted ions in a thin film transistor obtained by a method for fabricating a thin film transistor according to an embodiment of the third aspect of the present application.

### DETAILED DESCRIPTION OF THE EMBODIMENTS

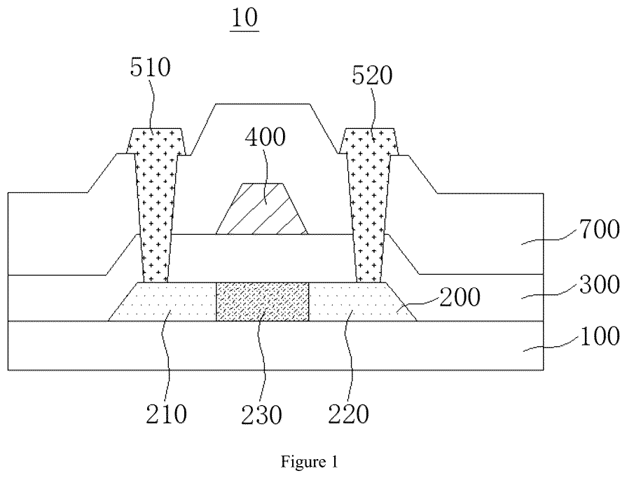

In order to better understand the present application, a thin film transistor, a display panel and a method for fabricating a thin film transistor according to embodiments of the present application will be described below with reference to FIGS. 1 to 11.

FIG. 1 is a structural schematic diagram of a thin film transistor 10 according to an embodiment of the present application.

As shown in FIG. 1, an embodiment of a first aspect of the present application provides a thin film transistor 10, where the thin film transistor 10 includes a substrate 100, an active layer 200, a gate insulation layer 300 and a gate electrode 400. The active layer 200 is formed on the substrate 100. The gate insulation layer 300 is located on a side of the active layer 200 facing away from the substrate 100. The gate electrode 400 is located on a side of the gate insulation layer 300 facing away from the active layer 200. In a direction from the gate insulation layer 300 to the substrate 100, the concentration of implanted ions in at least a partial region of the active layer 200 has a decreasing trend, and the concentration of implanted ions in the gate insulation layer 300 is less than the concentration of implanted ions in the active layer 200.

In the thin film transistor 10 according to the embodiment of the present application, the thin film transistor 10 includes the substrate 100, and the active layer 200, the gate insulation layer 300 and the gate electrode 400 that are arranged on the substrate 100. There are implanted ions in the active layer 200, and the concentration of the implanted ions in the active layer 200 has the decreasing trend in the direction from the gate insulation layer 300 to the substrate 100, that is, ion implantation energies for the active layer 200 vary at different positions in a thickness direction. The concentration of implanted ions in the gate insulation layer 300 is less than the concentration of implanted ions in the active layer 200, such that the impact of a concentration of implanted ions in the gate insulation layer 300 on the characteristics of the thin film transistor 10 can be reduced. In a direction close to the gate electrode 400, the doping concentration of the implanted ions in the active layer 200 increases, allowing current carriers to better flow at an interface of the active layer 200 facing the gate electrode 400, thereby relieving the problem of driving hysteresis of the thin film transistor 10. When the thin film transistor 10 is used in a display panel, the problem of display image sticking caused by the driving hysteresis of the thin film transistor 10 can be relieved.

In addition, when the implanted ions peak within the active layer 200, that is, the active layer 200 has the highest concentration of implanted ions within the active layer 200, the concentration of implanted ions at a position within the active layer 200 is greater than the concentration of implanted ions at the interface of the active layer 200 facing the gate electrode 400. In order to ensure that the active layer 200 has sufficient implanted ions at the interface thereof facing the gate electrode 400, it is necessary to increase the implantation concentration, a relatively large implantation energy will affect the structure of a crystalline crystal within the active layer 200 and thus the chemical and physical properties of the active layer 200, thereby affecting the characteristics of the thin film transistor 10. In the embodiment of the present disclosure, the concentration of implanted ions in the vicinity of the interface of the active layer 200 facing the gate electrode 400 is higher than those at other positions, that is, the implanted ions peak in the vicinity of the interface of the active layer 200 facing the gate electrode 400, and thus the requirement for the concentration of implanted ions at the interface of the active layer 200 facing the gate electrode 400 can be met by using a relatively small implantation energy, such that the impact of the implantation energy on the structure of the crystalline crystal within the active layer 200 can be reduced, and the yield and characteristic stability of the thin film transistor 10 is improved.

At least a partial region of the active layer 200 refers to at least a partial region of the active layer 200 within a planar region of a film layer, rather than at least a partial region of the active layer 200 in the thickness direction of the active layer 200.

Alternatively, as shown in FIG. 1, the thin film transistor 10 further includes a source electrode 510 and a drain electrode 520, and the source electrode 510 and the drain electrode 520 are connected to the active layer 200. The thin film transistor 10 may be configured in a variety of ways, and the thin film transistor 10 may be of a top gate structure or a bottom gate structure. In the present application, the thin film transistor 10 is of a top gate structure by way of example, that is, the source electrode 510 and the drain electrode 520 are located on a side of the gate electrode 400 facing away from the active layer 200. Alternatively, an insulation layer 700 is further arranged between the source electrode 510 and the drain electrode 520, and the gate electrode 400. Alternatively, the source electrode 510 and the drain electrode 520 are arranged in the same layer.

There are various configuration ways in which the concentration of implanted ions in the gate insulation layer 300 is less than the concentration of implanted ions in the active layer 200. For example, the implanted ions may be provided in the gate insulation layer 300, and the concentration of the implanted ions in the gate insulation layer 300 is less than the concentration of the implanted ions in the active layer 200.

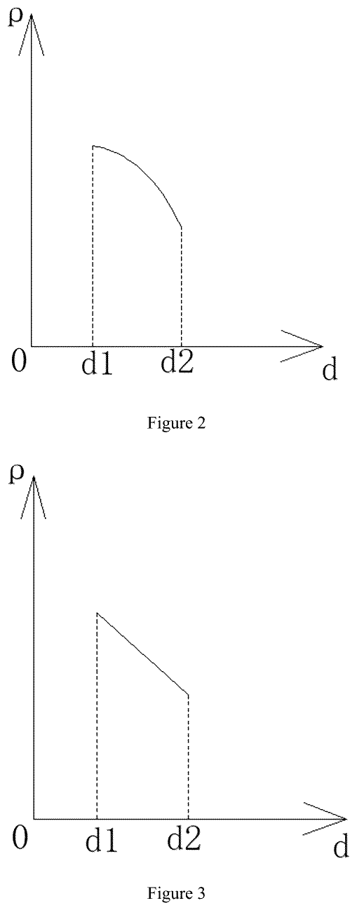

Referring to FIGS. 1 and 2 together, FIG. 2 is a graph of the concentration of implanted ions in the thin film transistor 10 according to the embodiment of the first aspect of the present application. The ordinate in FIG. 2 represents the concentration of implanted ions, and the abscissa represents a position of another film layer relative to the gate electrode 400 with the gate electrode 400 as a reference, where d1 represents the position of a contact interface between a gate insulation layer and the active layer 200, that is, d1 represents the thickness of the gate insulation layer. d2 represents a position where an interface on a side of the active layer 200 facing away from the gate electrode 400 is located, and d2−d1 represents the thickness of the active layer 200.

In some alternative embodiments of the present application, as shown in FIGS. 1 and 2, the concentration of implanted ions in the gate insulation layer 300 is zero. That is, no implanted ions are doped in the gate insulation layer 300. In a fabricating process of the thin film transistor 10, a sacrificial layer 600 may be provided on the active layer 200 before ions are implanted in the active layer 200. After the ions are implanted in the active layer 200, the sacrificial layer 600 may be removed, and the gate insulation layer 300 may be fabricated on the side of the active layer 200 facing away from the substrate 100 again.

In these alternative embodiments, since no implanted ions are contained in the gate insulation layer 300, the insulating property of the gate insulation layer 300 is not affected by the implanted ions, which can relieve the deterioration of the gate insulation layer 300, further improve the characteristics of the thin film transistor 10, and relieve the problem of driving hysteresis of the thin film transistor 10 and thus the problem of image sticking to improve the display effect of the display panel.

In some alternative embodiments, with continued reference to FIG. 1, the active layer 200 includes a source region 210, a drain region 220 and a channel region 230 located between the source region 210 and the drain region 220, an orthographic projection of the channel region 230 on the substrate 100 at least partially overlaps an orthographic projection of the gate electrode 400 on the substrate 100, and the concentration of implanted ions in the channel region 230 has a decreasing trend in the direction from the gate insulation layer 300 to the substrate 100.

Alternatively, the source region 210 and the source electrode 510 are connected to each other by means of a via, the drain region 220 and the drain electrode 520 are connected to each other by means of a via, and when the gate electrode 400 carries a signal, the channel region 230 can be conductive, thus allowing mutual communication between the source electrode 510 and the drain electrode 520 by means of the active layer 200.

In these alternative embodiments, the orthographic projection of the channel region 230 on the substrate 100 at least partially overlaps the orthographic projection of the gate electrode 400 on the substrate 100, a threshold voltage of the thin film transistor 10 depends on the concentration of implanted ions in the channel region 230, and the concentration of implanted ions in the channel region 230 is set to decrease in the direction from the gate insulation layer 300 to the substrate 100, that is, the concentration of implanted ions at an interface of the channel region 230 facing the gate electrode 400 is larger, such that the current carriers can better flow in the interface of the channel region 230 facing the gate electrode 400, and the problem of driving hysteresis of the thin film transistor 10 is relieved. When the thin film transistor 10 is used in a display panel, the problem of display image sticking caused by the driving hysteresis of the thin film transistor 10 can be relieved. In this implementation, the orthographic projection of the gate electrode 400 on the substrate 100 covers the orthographic projection of the channel region 230 on the substrate 100.

Alternatively, the concentration of implanted ions in the channel region 230 tending to decrease may be configured in a variety of ways. For example, in the direction from the gate insulation layer 300 to the substrate 100, the concentration of implanted ions in the channel region 230 gradiently decreases.

Referring to FIGS. 1 to 3 together, FIG. 3 is a graph of the concentration of implanted ions in the thin film transistor 10 according to another embodiment of the first aspect of the present application.

In some other alternative embodiments, as shown in FIGS. 1 to 3, the concentration of implanted ions in the channel region 230 decreases along a linear or arc-shaped trajectory in the direction from the gate insulation layer 300 to the substrate 100. That is, the concentration of implanted ions in the channel region 230 gradually decreases overall, and the concentration of implanted ions vary at different positions in the thickness direction of the active layer 200, that is, the active layer 200 have no parts having the same concentration of implanted ions at the different positions in the thickness direction. The concentration of implanted ions peaks at a contact interface between the channel region 230 and the gate insulation layer 300, that is, the concentration of implanted ions peaks in a front channel, which can reduce a back channel effect, i.e. the effect of the concentration of implanted ions peaking within the channel or on a side of the channel region 230 facing the substrate 100, reduce defects and damages within the channel, and improve the characteristic stability of the thin film transistor 10.

Alternatively, the concentration of implanted ions in the active layer 200 is greater than or equal to 8*10¹¹ cm². For example, the channel region 230 has a concentration of implanted ions in the range of 5*10¹¹ cm²-10*10¹¹ cm², which can relieve the driving hysteresis of the transistor caused by the excessive threshold voltage of the thin film transistor 10 due to a relatively low concentration of implanted ions; and which can also relieve the problem of the ion concentration being unable to meet the requirements due to too low concentration of implanted ions.

Alternatively, there are a variety of implanted ions, for example, the implanted ions include at least one of B₂H₆, BF₃ and PH₃.

An embodiment of a second aspect of the present application further provides a display panel, including a thin film transistor 10 according to any one of the above-described embodiments of the first aspect. Since the display panel according to the embodiment of the present application includes the thin film transistor 10 as described above, the display panel according to the embodiment of the present application has the beneficial effects of the thin film transistor 10 described above, which will not be described in detail herein.

Alternatively, the display panel includes at least a light-emitting unit and at least a drive circuit for driving the light-emitting unit to emit light. The drive circuit includes at least a drive transistor and at least a switch transistor, and the drive transistor is the thin film transistor 10 as described above, to better relieve the problem of image sticking of the display panel and improve the display effect of the display panel.

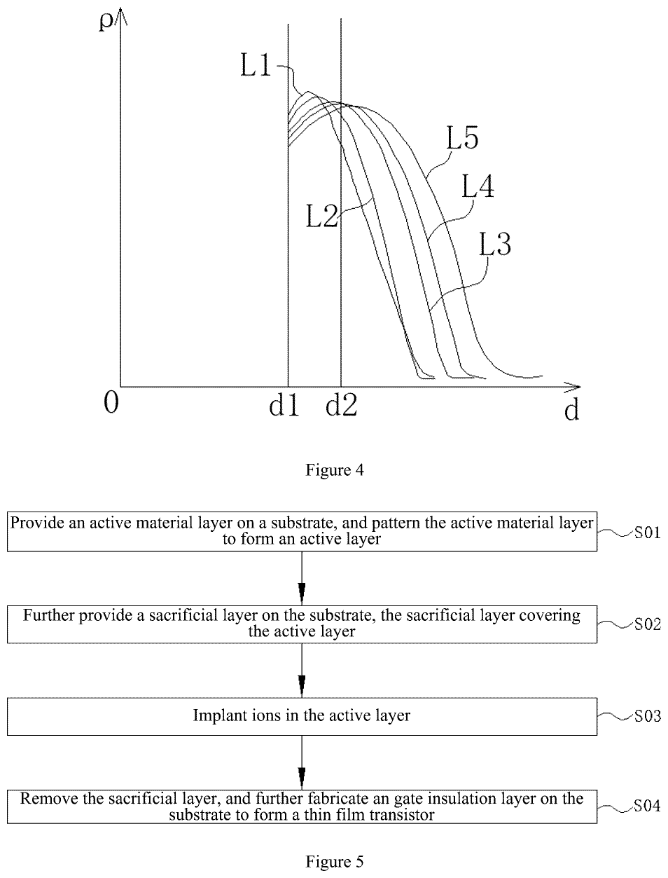

Referring to FIG. 4, FIG. 4 is a graph of the concentration of implanted ions in a method for fabricating a thin film transistor 10 provided in the related art. The abscissa represents a position, the ordinate represents the concentration of implanted ions, L1 represents a curve of the concentration of implanted ions obtained at an implantation energy of 5 eV, L2 represents a curve of the concentration of implanted ions obtained at an implantation energy of 7 eV, L3 represents a curve of the concentration of implanted ions obtained at an implantation energy of 10 eV, L4 represents a curve of the concentration of implanted ions obtained at an implantation energy of 12 eV, and L5 represents a curve of the concentration of implanted ions obtained at an implantation energy of 15 eV.

It can be seen from FIG. 4 that ions are implanted into the active layer 200 at the energies of 5 eV, 7 eV, 10 eV, 12 eV and 15 eV, respectively, the implanted ions peak within the active layer 200, or even the implanted ions peak within the active layer 200 on a side away from the gate electrode 400. For example, in the case of the ion implantation energies of 10 eV, 12 eV and 15 eV, the implanted ions peak within the active layer 200 on the side away from the gate electrode 400. As the implantation energy decreases, the implanted ions peak toward the gate electrode 400. For example, in the case of the ion implantation energies of 5 eV and 7 eV, the implanted ions peak within the active layer 200. However, when the ion implantation energy is too small, the ion implantation is difficult to implement.

When the implanted ions peak within the active layer 200, in order to provide sufficient implanted ions at the interface of the active layer 200 facing the gate electrode 400, it is necessary to increase the implantation energy, and an excessive implantation energy will affect the structure of the crystalline crystal within the active layer 200 and thus the chemical and physical properties of a material within the active layer 200. Therefore, there is a damage within the active layer 200 fabricated by means of the implantation method shown in FIG. 4, which affects the characteristics of the thin film transistor 10.

In this regard, an embodiment of a third aspect of the present application further provides a method for fabricating a thin film transistor 10. The thin film transistor 10 may be the thin film transistor 10 according to any one of the first aspect.

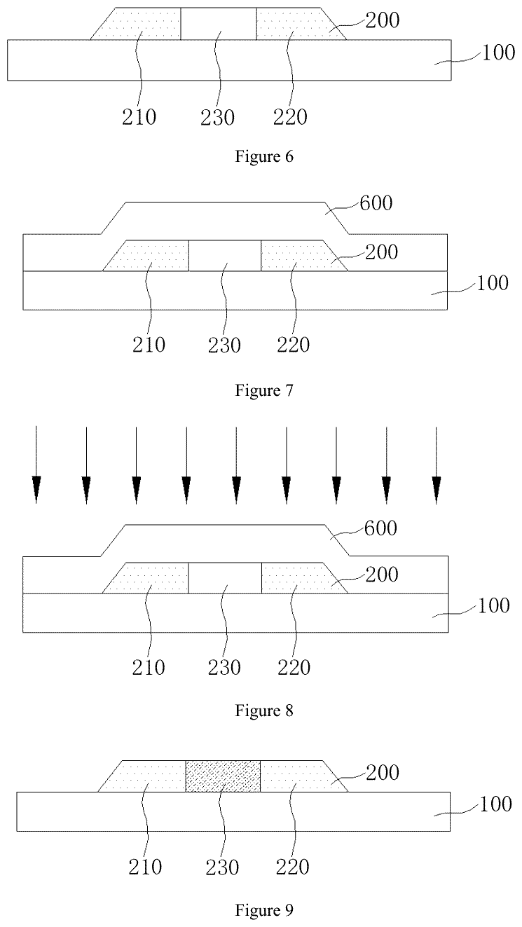

Referring to FIGS. 5 to 11 together, FIG. 5 is a schematic flow chart of the method for fabricating the thin film transistor 10 according to an embodiment of the third aspect of the present application, and FIGS. 6 to 10 are diagrams of a fabricating process of the method for fabricating the thin film transistor 10 according to an embodiment of the third aspect of the present application. FIG. 11 is a graph of the concentration of implanted ions in the thin film transistor 10 obtained by a method for fabricating the thin film transistor 10 according to an embodiment of the third aspect of the present application.

As shown in FIGS. 5 to 11, the method for fabricating the thin film transistor 10 includes the following steps.

In step S01, as shown in FIG. 6, an active material layer is provided on a substrate 100, and the active material layer is patterned to form an active layer 200.

In step S02, as shown in FIG. 7, a sacrificial layer 600 is further provided on the substrate 100, and the sacrificial layer 600 covers the active layer 200.

In step S03, as shown in FIG. 8, ions are implanted in the active layer 200.

As described above, the active layer 200 includes a source region 210, a drain region 220 and a channel region 230 between the source region 210 and the drain region 220, and then ions are implanted in the channel region 230 in step S03.

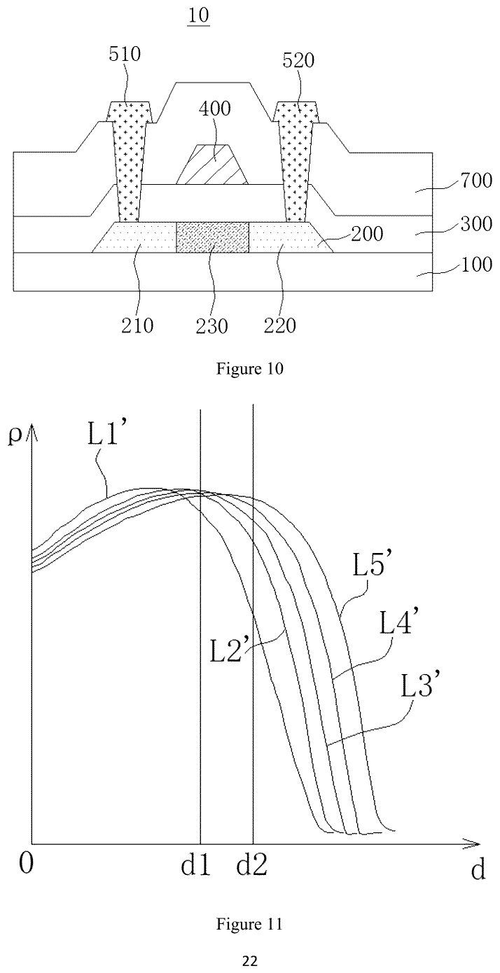

In step S04, as shown in FIGS. 9 and 10, the sacrificial layer 600 is removed, and the gate insulation layer 300 is further fabricated on the substrate 100 to form the thin film transistor 10.

Alternatively, in step S04, the sacrificial layer 600 may be removed by using a wet etching process which is technologically mature and makes the fabrication easy. Alternatively, in step S04, after the gate insulation layer 300 is formed, a gate electrode 400, an insulation layer, a source electrode 510 and a drain electrode 520 may also be further fabricated on the gate insulation layer 300 to form the thin film transistor 10.

In the method for fabricating the thin film transistor 10 according to the embodiment of the present application, the active material layer is first provided in step S01, and then the sacrificial layer 600 is provided on the active layer 200 in step S02.

When ions are implanted in the active layer 200 in step S03, due to the presence of the sacrificial layer 600, during the ion implantation, by adjusting an implantation parameter, the implanted ions can be adjusted to have a wave crest at a contact interface between the active layer 200 and the sacrificial layer 600, or the implanted ions can be directly adjusted to have a wave crest within the sacrificial layer 600, such that the concentration of implanted ions within the active layer 200 has a decreasing trend in the direction from the gate insulation layer 300 to the substrate 100, that is, the ion implantation energies for the active layer 200 vary at different positions in the thickness direction. The concentration of implanted ions is higher at the interface of the active layer 200 facing the gate electrode 400, allowing current carriers to better flow in the interface of the active layer 200 facing the gate electrode 400, thereby relieving the problem of driving hysteresis of the thin film transistor 10. When the thin film transistor 10 is used in a display panel, the problem of display image sticking caused by the driving hysteresis of the thin film transistor 10 can be relieved.

As shown in FIG. 11, the abscissa indicates a position, the ordinate indicates the concentration of implanted ions, d1 represents a thickness of the sacrificial layer 600, and d1 may be, for example, 1400 Å. L1′ represents a curve of the concentration of implanted ions obtained at an implantation energy of 25 eV, L2′ represents a curve of the concentration of implanted ions obtained at an implantation energy of 30 eV, L3′ represents a curve of the concentration of implanted ions obtained at an implantation energy of 33 eV, L4′ represents a curve of the concentration of implanted ions obtained at an implantation energy of 36 eV, and L5′ represents a curve of the concentration of implanted ions obtained at an implantation energy of 40 eV.

It can be seen from FIG. 11 that the ions are implanted into the active layer 200 at the energies of 25 eV, 30 eV, 33 eV, 36 eV and 40 eV, respectively, the implanted ions peak in the sacrificial layer 600 or in the vicinity of the contact interface between the sacrificial layer 600 and the active layer 200. Therefore, in a direction close to the gate electrode 400, the concentration of implanted ions in the active layer 200 is increasingly high, allowing the current carriers to better flow in the interface of the active layer 200 facing the gate electrode 400, thereby relieving the problem of driving hysteresis of the thin film transistor 10. In addition, the ion implantation can be performed by using a relatively large implantation energy, which ensures that the concentration of implanted ions in the active layer 200 meets the requirements.

Furthermore, in step S04, the sacrificial layer 600 is removed and the gate insulation layer 300 is re-fabricated. As shown in FIG. 11, no implanted ions are contained in the gate insulation layer 300, which can relieve the problem of occurrence of defects of the gate insulation layer 300 in the step of ion implantation, and can improve the yield of the thin film transistor 10.

Therefore, in the embodiments of the present application, by adding the sacrificial layer 600 in the step of ion implantation, the defect of implantation energy for implanting ions in the active layer 200 can be relieved, and by removing the sacrificial layer 600 and re-fabricating the gate insulation layer 300 after the step of ion implantation, the defects of the gate insulation layer 300 can be relieved, and the yield of the thin film transistor 10 is improved.

Alternatively, step S02 may be configured in a variety of ways, and in some alternative embodiments, step S02 includes: cleaning the active layer 200 with O³ to form the sacrificial layer 600 containing oxide.

Alternatively, when the active layer 200 is cleaned with O³ to form the sacrificial layer 600 containing oxide, the sacrificial layer 600 may have a thickness in the range of 1 nm-5 nm.

In these alternative embodiments, a material of the active layer 200 contains silicon or the like. When the active layer 200 is cleaned with O³, O³ can react with the silicon material in the active layer 200 to form the sacrificial layer 600 containing the oxide, such as silicon oxide. A method for fabricating the sacrificial layer 600 is easy, such that the fabricating process for the thin film transistor 10 is simplified.

In some other alternative embodiments, the sacrificial layer 600 containing the silicon oxide is formed by means of chemical vapor deposition.

Alternatively, when the sacrificial layer 600 containing the silicon oxide is formed by means of the chemical vapor deposition, the sacrificial layer 600 may have a thickness in the range of 5 nm-150 nm.

In these alternative embodiments, a silicon oxide material may be directly deposited on the active layer 200 to form the sacrificial layer 600, which can relieve the impact of the fabrication of the sacrificial layer 600 on the thickness of the active layer 200 or on an internal material, and improve the yield of the thin film transistor 10.

In some alternative embodiments, the material of the sacrificial layer 600 and/or the gate insulation layer 300 contains an amorphous insulation material to allow the sacrificial layer 600 and/or the gate insulation layer 300 to have good insulating properties.

In some alternative embodiments, the sacrificial layer 600 is made of the same material as the gate insulation layer 300. In the embodiments of the present application, the same material is used for the sacrificial layer 600 and the gate insulation layer 300, such that the fabricating process for the thin film transistor 10 can be simplified, and after the sacrificial layer 600 is removed, the gate insulation layer 300 may be fabricated by using the same process and apparatus as the sacrificial layer 600.

In some alternative embodiments, in step S03, the implantation energy may be in the range of 5 KeV-40 KeV. For example, the implantation energy is in the range of 30 KeV-36 KeV. When the ion implantation energy is within the above range, the implanted ions can be configured to have a wave crest at the contact interface between the active layer 200 and the sacrificial layer 600, or the implanted ions can be configured to have a wave crest within the sacrificial layer 600.

What is claimed is:

1. A thin film transistor, comprising:
a substrate;
an active layer formed on the substrate;
a gate insulation layer located on a side of the active layer facing away from the substrate; and
a gate electrode located on a side of the gate insulation layer facing away from the active layer;
wherein in a direction from the gate insulation layer to the substrate, a concentration of implanted ions in at least a partial region of the active layer has a decreasing trend, and a concentration of implanted ions in the gate insulation layer is less than a concentration of implanted ions in the active layer.

2. The thin film transistor according to claim 1, wherein the concentration of implanted ions in the gate insulation layer is zero.

3. The thin film transistor according to claim 1, wherein the active layer comprises a source region, a drain region and a channel region located between the source region and the drain region, an orthographic projection of the channel region on the substrate at least partially overlapping an orthographic projection of the gate electrode on the substrate, and the concentration of implanted ions in the channel region has a decreasing trend in the direction from the gate insulation layer to the substrate.

4. The thin film transistor according to claim 3, wherein the thin film transistor further comprises a source electrode and a drain electrode, the source electrode being connected to the source region by means of a via, and the drain electrode being connected to the drain region by means of a via.

5. The thin film transistor according to claim 3, wherein the concentration of implanted ions in the channel region decreases along a linear or arc-shaped trajectory in the direction from the gate insulation layer to the substrate.

6. The thin film transistor according to claim 1, wherein the concentration of implanted ions in the active layer is in the range of 5*10¹¹ cm²-10*10¹¹ cm².

7. The thin film transistor according to claim 1, wherein the concentration of implanted ions in the active layer 200 is greater than or equal to 8*10¹¹ cm².

8. The thin film transistor according to claim 3, wherein the concentration of implanted ions in the channel region of the active layer is in the range of 5*10¹¹ cm²-10*10¹¹ cm².

9. The thin film transistor according to claim 1, wherein the implanted ions comprise at least one of B₂H₆, BF₃ and PH₃.

10. A method for fabricating a thin film transistor, the method comprising:
providing an active material layer on a substrate, and patterning the active material layer to form an active layer;
further providing a sacrificial layer on the substrate, the sacrificial layer covering the active layer;
implanting ions in the active layer; and
removing the sacrificial layer, and further fabricating a gate insulation layer on the substrate to form the thin film transistor.

11. The method according to claim 10, wherein in the step of further providing a sacrificial layer on the substrate, the sacrificial layer covering the active layer:
the active layer is cleaned with O³ to form the sacrificial layer containing oxide, and the sacrificial layer has a thickness in the range of 1 nm-5 nm;
or the sacrificial layer containing silicon oxide is formed by means of chemical vapor deposition, and the sacrificial layer have a thickness in the range of 5 nm-150 nm.

12. The method according to claim 11, wherein a material of the sacrificial layer and the gate insulation layer contains an amorphous insulation material.

13. The method according to claim 11, wherein the sacrificial layer is made of the same material as the gate insulation layer.

14. The method according to claim 10, wherein in the step of implanting ions in the active layer: an implantation energy is in the range of 5 KeV-40 KeV.

15. The method according to claim 14, wherein in the step of implanting ions in the active layer: the implantation energy is in the range of 30 KeV-36 KeV.

16. The method according to claim 10, wherein the active layer comprises a source region, a drain region and a channel region between the source region and the drain region, and in the step of implanting ions in the active layer: ions are implanted in the channel region.

17. A display panel, comprising a thin film transistor of claim 1.
